(19) United States
(12) Patent Application Publication
(10) Pub. No.: US 2024/0384036 A1
(43) Pub. Date: Nov. 21, 2024

(54) GRADIENT GLASS-LIKE CERAMIC STRUCTURES AND BOTTOM-UP FABRICATION METHOD THEREOF

(71) Applicant: Gelest, Inc., Morrisville, PA (US)

(72) Inventors: Barry C. ARKLES, Pipersville, PA (US); Kerry Campbell DEMELLA, Philadelphia, PA (US); Jonathan D. GOFF, Philadelphia, PA (US)

(21) Appl. No.: 18/787,633

(22) Filed: Jul. 29, 2024

Related U.S. Application Data
(63) Continuation of application No. 17/220,601, filed on Apr. 1, 2021, now abandoned.
(60) Provisional application No. 63/005,506, filed on Apr. 6, 2020.

(51) Int. Cl. C08G 77/18; C23C 18/12; C23C 18/14

(52) U.S. Cl. CPC C08G 77/18; C23C 18/122; C23C 18/143

(57) ABSTRACT

Thin glass-like ceramic films which possess organic or physically functional structures with thicknesses in the 15 to 500 nm range and bottom-up methods for their fabrication are described. SiO₂-rich structures having gradient properties are formed from a silsesquioxane having an electronegative β substituent and at least one organofunctional silane or at least one metal alkoxide.

### CROSS-REFERENCE TO RELATED APPLICATION

This application is a continuation of co-pending U.S. patent application Ser. No. 17/220,601, filed Apr. 1, 2021, which claims priority to U.S. Provisional Application No. 63,005,506, filed Apr. 6, 2020, the disclosures of which are herein incorporated by reference in their entirety.

### BACKGROUND OF THE INVENTION

Silicon dioxide (SiO₂) thin films and substrates are essential structural components of diagnostic, optical, and microelectronic devices that are currently in widespread usage. These SiO₂-containing thin films are generally created using milling and etching techniques or well-known silanes, e.g., SiH₄, silane esters, e.g., tetraethoxysilane (TEOS), or silsesquioxanes, e.g., hydrogen silsesquioxane resins such as described in U.S. Pat. No. 5,290,354 of Haluska and U.S. Pat. No. 5,320,868 of Ballance et al. The objective of all of these techniques is to create a uniform mechanic, optical, or electronic structure that is stable and not interactive or affecting chemical or wetting processes of the device. Essentially, the devices requires that the glass or glass-like structure be an inert structural component.

Sommer et al., “Organosilicon Compounds V. β-Eliminations Involving Silicon,” J. Amer. Chem. Soc., 68, pp. 1083-1085 (1946) summarizes chemical reaction studies of β-chloroethyltrichlorosilane and β-chloro-n-propyltrichlorosilane, including synthesis of β-chloroethyl silicone. The β-chloroethyl silicone polymer, having a formula ClCH₂CH₂SiO_{1.5}, was reacted with dilute alkali to give ethylene and Si(OH)₄. No end use applications for these compounds were suggested.

### SUMMARY OF THE INVENTION

According to one embodiment, the disclosure relates to a SiO₂-rich structure having gradient properties, wherein the structure is formed from a silsesquioxane having an electronegative β substituent and at least one organofunctional silane.

A further aspect of the disclosure relates to a SiO₂-rich structure having a gradient concentration of at least one metal oxide selected from the group consisting of oxides of germanium, tantalum, titanium, zirconium and hafnium, wherein the structure is formed from a corresponding metal alkoxide and a silsesquioxane having an electronegative β substituent.

A still further aspect of the disclosure relates to a method for forming a SiO₂-rich structure having a gradient property, the method comprising preparing a coating composition comprising a silsesquioxane having an electronegative β substituent, at least one organofunctional silane, and optionally a solvent, coating the mixture onto a substrate, and heating and/or UV irradiating the coated substrate.

An additional aspect of the disclosure relates to a method for forming a SiO₂-rich structure having a gradient property, the method comprising preparing a coating composition comprising a silsesquioxane having an electronegative β substituent, at least one metal alkoxide, and optionally a solvent, coating the mixture onto a substrate, and heating and/or UV irradiating the coated substrate.

### BRIEF SUMMARY OF THE DRAWINGS

FIG. 1 is a diagram illustrating the synthesis of a product according to one embodiment of the present disclosure.

### DETAILED DESCRIPTION OF THE INVENTION

Aspects of the disclosure relate to thin glass-like ceramic films which possess organic or physically functional structures with thicknesses in the 15 to 500 nm range and bottom-up methods for their fabrication. The physicochemical nature of these structures possess spatial gradient character, i.e., properties that changes over a certain length in space. The structures and method described herein overcome previous challenges in the fabrication of high density silicon dioxide at low temperatures, in which gradients are induced by diffusion, etching, or varying energy intensity of thermal, photolytic or other energetic methods of preceramic to ceramic conversion. The technology described herein allows for microcontact printing and direct-write of silicon dioxide (SiO₂)-based ceramics at low temperatures (<250° C.) with the ability to adjust surface and bulk functionality. Transparent glass-like ceramic structures consistent with bottom-up processing can be deposited by spin-on, direct-write, or micro-contact printing techniques. The coatings are non-permeable and can resist a wide range of fluids, ranging from pH-extreme aqueous systems to solvent-based systems, without distortion or failure of the channels. The method also allows localized alterations of the surfaces by a variety of surface patterning techniques. This bottom-up approach facilitates complex device fabrication compared to etch-down and abrasive milling procedures.

As described in more detail below, the process for creating SiO₂-rich materials or structures with gradient properties according to one embodiment of the disclosure involves combining one or more organofunctional silanes, such as organofunctional alkoxysilanes, with a silsesquioxane base polymer having electronegative β-substitution.

The β substituent of the silsesquioxane base polymer is located on the β carbon of the alkyl group, sometimes referred to as the 2-carbon position, located with respect to the carbon-silicon bond. The β-substituted alkyl group is bound to the silicon at the α- or 1-carbon position.

U.S. Pat. Nos. 5,853,808 and 6,770,726, herein incorporated by reference in their entirety, and publications J. Sol-Gel Sci Tech, 8, 465 (1997) and J. Mater. Res. 14 (3), 990 (1999) demonstrate that organosilsesquioxanes with electron withdrawing substituents in the β position undergo a conversion to SiO₂ through an intermediate structure by a chemical pathway that involves the elimination of ethylene and then a hydrolytic condensation, as shown in Scheme 1below. The conversion can be initiated by thermal or UV exposure. These materials will be referred to herein as “silsesquioxane base polymers.”

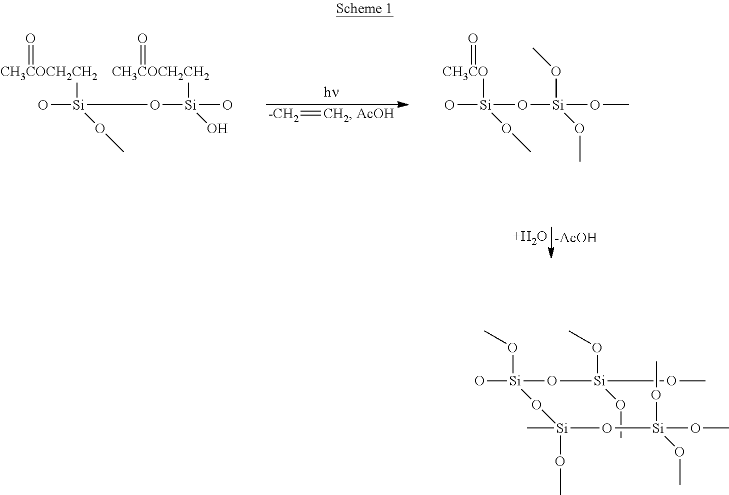

The silsesquioxane base polymers can also include partial substitutions of the polymer backbone by the electronegative group attached directly to silicon atom of the backbone rather than through a CH₂CH₂ linkage, as in acetoxyethylsilsesquioxane-acetoxysilsesquioxane copolymer. The silsesquioxane base polymer can also include other copolymers in which a hydrolyzable alkoxy group is present, such as acetoxyethylsilsesquioxane-ethoxysilsesquioxane copolymer and acetoxyethylsilsesquioxane-methoxypropoxysilsesquioxane copolymer, but it is preferred that the hydrolyzable substitution constitute less than 20% of the copolymer. The alkoxysilsesquioxane or substituted alkoxysilsesquioxanes copolymers may be readily formed by warming or storing the silsesquioxane homopolymers in solutions containing an alcohol, such as ethanol, methoxyethanol, or methoxypropanol. In preferred embodiments, 2-acetoxyethyl groups are the preferred primary comonomer and alkylether-substituted alkoxy groups are preferred substituents for the secondary comonomer.

Upon subsequent heating of the β-substituted organosilsesquioxane base polymers at relatively moderate temperature conditions, e.g., above about 150° C., or by exposure to ultraviolet radiation, the labile β-substituted alkyl groups appear to be volatilized and substantially eliminated and the silsesquioxane polymer is converted to a SiO₂-rich ceramic material, suitable for preparing thin films or layers on electronic substrates.

An exemplary reaction for forming the SiO₂-rich structures having gradient properties as described herein is shown in Scheme 2.

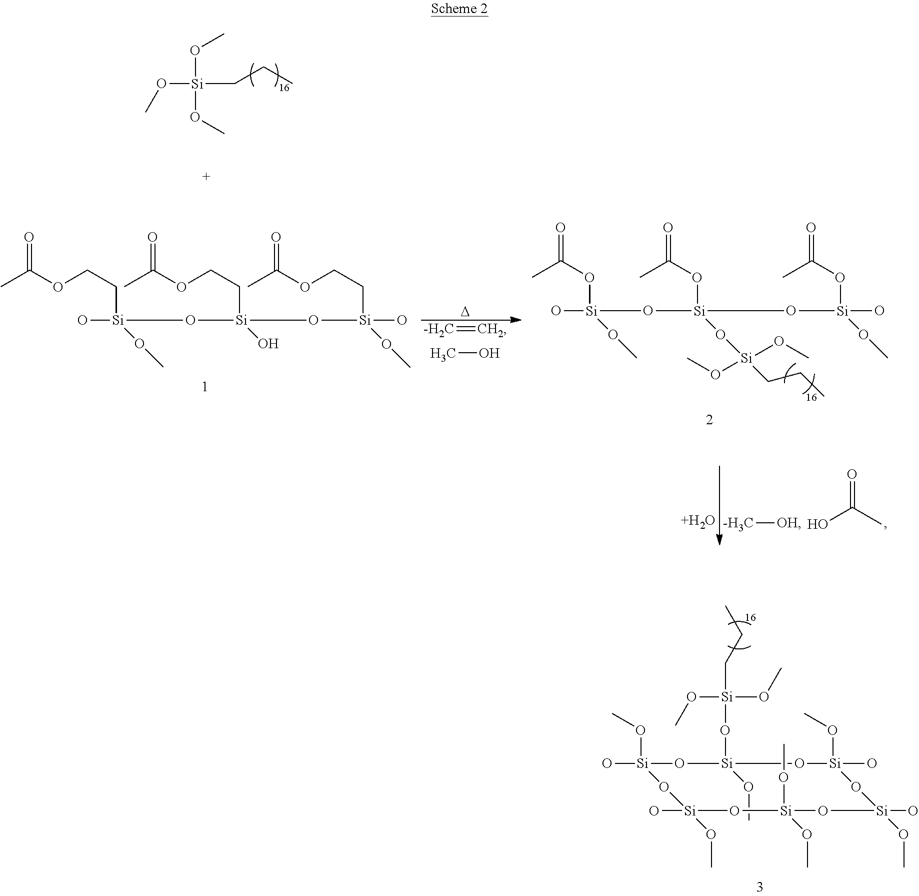

Upon heating, the silsesquioxane base polymer (structure 1 in Scheme 2), which has residual hydroxyl groups, condenses with an organofunctional alkoxysilane, forming the intermediate silsesquioxane of this disclosure (structure 2 in scheme 2). Such inventive organofunctional silane modified silsesquioxane base polymers, will be referred to herein as “silsesquioxane deposition polymers.” The silsesquioxane deposition polymers are formed by the reaction of the hydroxyl (silanol) groups of the silsesquioxane base polymers with organofunctional alkoxysilanes or metal alkoxides. The heating simultaneously drives a condensation reaction in which a hydroxyl group on the silsesquioxane displaces an alkoxy group, liberating an alcohol, and a rearrangement reaction in which the acetoxy groups migrate to silicon with loss of ethylene. In a second moisture driven step, the acetoxy groups are hydrolyzed and condensation to a ceramic resin occurs. Not shown, but understood, is that the second stage hydrolysis-condensation reaction entails the formation of silanols which can react with any remaining alkoxy groups of the alkoxysilane. In the case when the silsesquioxane base polymer includes copolymers in which a hydrolyzable group is present, such as in acetoxyethylsilsesquioxane-methoxypropoxysilsesquioxane copolymer, it is preferable to perform the deposition in a high humidity environment to initiate the conversion of the hydrolyzable groups to silanols.

The silsesquioxane deposition polymers which are appropriate for forming the SiO₂-rich structures of the present disclosure are the polymeric reaction products obtained from the β-substituted alkyl silsesquioxane base polymers which are derivatized by the addition of an organofunctional silane prior to or simultaneously with conversion to a SiO₂-rich material. The organosilane has the general formula RₙSiX₍₄₋ₙ₎ where n is 1 or 2; X is a hydrolyzable group selected from the group consisting of chlorine, bromine, fluorine, and iodine, or preferably an alkoxy group selected from the group consisting of methoxy, ethoxy and propoxy substituents.

A highly preferred β-substituted organosilsesquioxane base polymer is the polymeric reaction product that is obtained from the hydrolysis and condensation polymerization of an organosilane containing a β-substituted ethyl group; preferred organosilanes include, but are not limited to, β-acetoxyethyltrimethoxysilane CH₃COOCH₂CH₂Si(OCH₃)₃ and acetoxyethyltrichlorosilane CH₃COOCH₂CH₂SiCl₃, which contain hydroxyl groups bound to silicon (silanol groups) as depicted in the first structure of scheme 2.

The silsesquioxane base polymer is preferably a polymeric reaction product that is obtained from homopolymerization of the organosilane. In alternative embodiments, the β-substituted organosilsesquioxane polymer may be a polymeric reaction product that is obtained from copolymerization of the organosilane with an alkoxysilane, e.g., a tetraalkoxysilane or organic substituted alkoxysilane. The alkoxysilane is preferably selected from the group consisting of tetraalkoxysilanes such as tetraethoxysilane (TEOS), tetramethoxysilane (TMOS), and methoxytriethoxysilane, triethoxychlorosilane, and organic substituted alkoxysilanes such as bis(trimethoxysilyl)ethane, methyltriethoxysilane, vinyltriethoxysilane, pentafluorophenyltriethoxysilane, tridecafluorooctyl-1H,2H,2H-octyltriethoxysilane, and phenyltrimethoxysilane.

The silsesquioxane base polymers, obtainable from the hydrolysis and condensation polymerization reaction of β-substituted organosilanes, must contain free silanol groups (Si—OH), i.e., unreacted or non-condensed silanol groups. Preferred silsesquioxane base polymers contain at least about five silanol groups per 100 silicon atoms, up to about 75 silanol groups per 100 silicon atoms, in the polymeric reaction product. More preferably, the silsesquioxane base polymers contain about 20 to about 50 silanol groups per 100 silicon atoms in the polymeric reaction product.

The free silanol content in the polymeric reaction product is preferably high, and this can be maintained by neutralizing the reaction mixture and recovering the polymeric reaction product and maintaining the polymer as a solution in a polar solvent.

The silsesquioxane base polymers are obtained by the hydrolysis and condensation of the β-substituted organosilane, either in the homopolymerization of the organosilane monomer or its copolymerization as described above. The hydrolysis and condensation polymerization reactions are exothermic and may be controlled via factors that are typically important in such hydrolysis and condensation reactions, and some of these are described below.

The hydrolysis and condensation polymerization may be carried out in conventional equipment by the addition of the organosilane monomer (or both monomers in the case of copolymerization) to an aqueous medium. The aqueous medium may be simply water or may be an aqueous alcohol. The monomer may be added neat or may be first solubilized in a solvent, e.g., methylene chloride. The monomer is preferably added at a measured rate, e.g., slowly, to the aqueous medium to obtain more precise control of the hydrolysis and condensation.

Additional control of the hydrolysis and condensation polymerization reactions may also be obtained through adjustment of the temperature of the aqueous reaction medium by maintaining the reaction temperature in the range of about 0° C. to about 50° C. Preferably, the temperature of the aqueous reaction medium is maintained at a temperature around (but above) the freezing point of the aqueous medium, about 0° C. to about 5° C. being preferred.

At the preferred reaction temperatures, the hydrolysis and condensation reactions occur more slowly. This permits, for example, the level of silanol content in the polymeric reaction product to be adjusted with greater control and precision. The preferred hydrolyzable substituent is an alkoxy group since hydrolysis is less exothermic even when catalyzed by acid and generally results in a silsesquioxane base polymer with a higher hydroxyl content.

Recovery of the polymeric reaction product, i.e., the β-substituted organosilsesquioxane base polymers, from the aqueous reaction medium may be carried out using conventional techniques, e.g., solvent extraction (with organic solvents that solubilize the polymeric reaction product but are immiscible with the aqueous reaction medium), salting-out of the polymeric reaction product, and the like. The polymeric reaction product may then be recovered as a substantially pure material (i.e., polymer) in solid form, by filtration or evaporation of the extract solvent as applicable.

### Silsesquioxane Deposition Polymers

Preferred soluble and liquid homopolymer and copolymer silsesquioxanes with substitution in the β position of the organic substituent include halogens, such as 2-choroethylsilsesquioxane and 2-bromoethylsilsesquioxane, ethers, such as 2-methoxethylsilsesquioxane, and carboxylates, such as 2-acetoxyethylsilsequioxane. These materials may be considered to be the base polymers that can be thought of as the continuous structure which is then modified by varying one or more co-reacting components to form a gradient upon ceramic conversion.

At the point of the syntheses when there is no alkoxysilane or metal oxide being added with the silsesquioxane, the base polymer becomes a deposition polymer. In the examples described below, at the exact mid-point, the unmodified silsesquioxane base polymer is present; at all other points during the synthesis it is modified by the alkoxysilane or metal oxide co-reacting component or additive.

Because inorganic acid byproducts are likely to react with organic substituents, the acetoxy group is preferred in the β position since acetic acid is the byproduct. The preferred organosilsesquioxanes of the present disclosure are 2-acetoxyethylsilsesquioxanes and more preferably those with hydroxyl substitution on the polymer backbone, denoted as silanols. An exemplary preferred silsesquioxane, acetoxysilsesquioxane, has formula (I), where R is 2-acetoxyethyl (CH₃COOCH₂CH₂—).

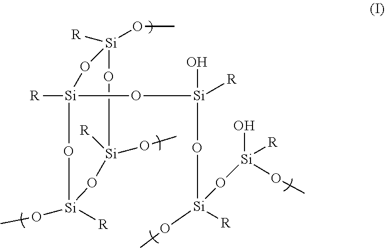

### Organofunctional Silanes

Appropriate organofunctional silanes for forming the SiO₂-rich structures described herein are preferably organofunctional alkoxysilanes. It is within the scope of the disclosure to include one, two, or more of these silanes when preparing the SiO₂-rich structures. Appropriate alkoxysilanes are generally trialkoxysilanes but dialkoxysilanes may also be used, in which the alkoxy group is methoxy or ethoxy (which lead to volatile byproducts having low masses), such as those containing alkyl substituents (dialkyldialkoxysilanes, alkyltrialkoxysilanes). Preferred alkoxy groups include methoxy and ethoxy. While it is within the scope of the disclosure to utilize silanes having higher alkoxy groups such as propoxy and isopropoxy, the resulting films are more prone to cracking. Appropriate alkyl groups including those having from one carbon atom (methyl) to more than twenty carbon atoms. It is also with the scope of the disclosure for the alkyl group to be substituted, such as with methoxy(polyethyleneoxy) groups. It is also within the scope of the disclosure to utilize silanes containing aromatic substituents, such as, without limitation, phenyltrimethoxysilane. Preferred alkoxysilanes include isobutyltriethoxysilane and methoxy(polyethyleneoxy)propyltrimethoxysilane, shown below.

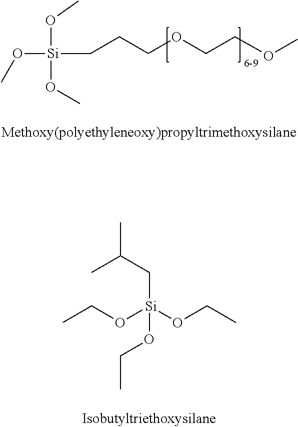

### Metal Alkoxides

It is also within the scope of the disclosure to replace the alkoxysilane(s) with one or more metal alkoxides, such as, but not limited to, germanium isopropoxide to produce germanium oxide gradients, tantalum ethoxide to produce tantalum oxide gradients, titanium n-butoxide to produce titanium oxide gradients, zirconium n-propoxide to produce zirconium oxide gradients, and hafnium n-butoxide to product hafnium oxide gradients. Use of these metal oxides will result in a SiO₂-rich structure which incorporates such elements and, among other properties, produces gradients in refractive index which have application in optical devices such as lenses, waveguides, and fiber optics. An exemplary reaction scheme is shown below in Scheme 3.

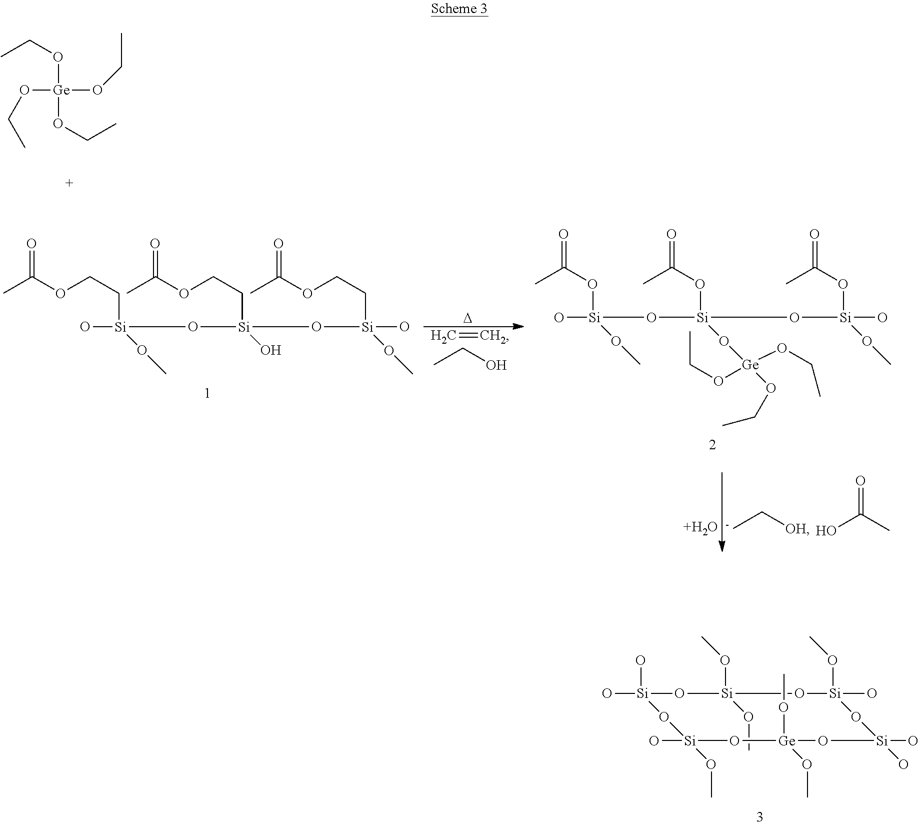

### SiO₂-Rich Structures With Gradient Properties

The term SiO₂-rich is used in this disclosure to describe a material in which the plurality of silicon atoms are each bonded to four oxygen atoms and no more than about 50% of the silicon atoms are bonded to carbon atoms.

The SiO₂-rich structures are preferably in the form of thin films having thicknesses of about 15 nm to about 500 nm. It is also within the scope of the disclosure to prepare thicker films, such as those having thicknesses of up to 1500 nm, but such films may be more likely to have stress cracks or imperfections.

Formation of non-planar active structures which can be written as lines may be achieved by combining the silsesquioxane base polymers described above with metal alkoxides, including organo-functional silanes, such as the organofunctional alkoxysilanes described above, and metal alkoxides such as germanium ethoxides, prior to performing an elimination-condensation reaction. Incorporation of the organic functionality can be introduced during dispensing and/or writing in a manner to change concentrations and create gradients. In a spin-on deposition methodology, the deposition polymer could create a refractive index gradient by increasing the concentration of germanium alkoxide. Thus, the outer portion of the film would have a relatively low refractive index while the central portion would have a higher refractive index. The ceramic structure, although planar, would behave like a convex lens.

The resulting materials are ceramic-like structures, preferably films, with sufficient organic functionality to create an active surface structure. During the conversion to glass-like ceramic structures, the metal becomes incorporated into the structure and, in the case of organo-functional silanes, the organic group as well, provided that the organic functionality is stable under the conversion conditions. At temperatures less than about 300° C., organo-functional SiO₂ films are readily formed. Thus, adding at least one organofunctional alkoxysilane to the silsesquioxane base polymer allows for organic functionality to be introduced during dispensing/writing, changing concentrations and creating gradients.

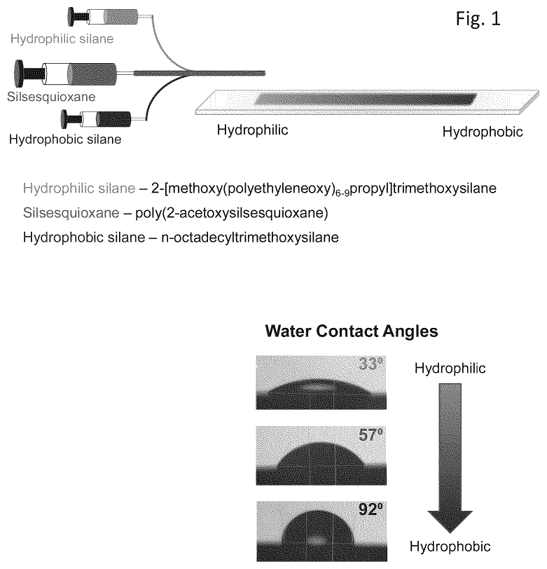

For example, SiO₂-rich structures may be formed from two organofunctional silanes having different hydrophobic/hydrophilic properties, such as one hydrophobic silane and one hydrophilic silane. During deposition of the SiO₂-rich film, the relative ratios of the hydrophilic and hydrophobic ratios may be varied so that the coating composition initially contains, in addition to the silsesquioxane, a larger percentage of the hydrophilic silane and a smaller percentage (or none) of the hydrophobic silane, with the relative amounts of the two silane changing during deposition so that they are equal in the middle of the deposition and then reversed at the end. That is, there is a larger percentage of the hydrophobic silane and a smaller percentage (or none) of the hydrophilic silane at the end of the deposition. The resulting material will exhibit gradient hydrophilic/hydrophobic properties: more hydrophilic on one end and more hydrophobic on the other end. Such varying hydrophilic/hydrophobic properties may be observed by applying droplets of water to the SiO₂-rich structure and observing the differences in wettability and spreading from one end to the other, or by measuring the contact angles at the two ends. An exemplary synthesis is shown in FIG. 1.

When only one alkoxysilane (or metal alkoxide, as described below) is employed, varying the relative concentration of this component in the coating composition will lead to gradient properties from one end of the structure or film to the other. Gradient properties are not limited to hydrophilicity/hydrophilicity, but may also include, without limitation, refractive index and covalent reactivity.

The process described herein can also be used as a convenient method for incorporating different metal oxides such as germanium oxide, tantalum oxide, titanium oxide, zirconium oxide, and hafnium oxide into a SiO₂-rich structure in which the metal oxide concentration is varied. The conversion process provides a method of building thin SiO₂ structures on a variety of substrates via bottom-up fabrication. Structures incorporating the oxides of these other elements, such as germanium, titanium, zirconium, hafnium and tantalum can form gradient refractive index (GRIN) structures. Since these materials lack organic content, they can be processed at higher temperatures.

The SiO₂-rich materials described herein can be applied by spin-on deposition, microcontact printing, 3-D printing, or direct write using methods which are well known in the art or to be developed to generate films of homogeneous/uniform character and achieve densities exceeding 80% of thermally grown oxides, if desired. In the case of direct-write, films with gradient functionality can be achieved by continuously adjusting relative flow rates of the components. Variable functionality can include hydrophobic-hydrophilic balance, refractive index, and/or covalent reactivity. The resulting materials are ceramic-like compositions which are generated as thermally stable physical elements.

While not wishing to be bound by theory, the apparent mechanism for the incorporation is principally the acid-induced hydrolytic condensation pathway that is available after the elimination stage of the ceramic conversion reaction. The presence of silanols in the silsesquioxanes appears to be beneficial. High concentrations of silanol (hydroxyl) groups are desirable since they promote reaction with the alkoxysilanes.

During deposition, an intermediate composition forms as the alkoxysilane or metal alkoxide is dispensed into the reaction mixture. In a specific example of a material produced from 2-acetoxyethylsilsesquioxane, isobutyltriethoxysilane, and methoxy(polyethyleneoxy)propyltrimethoxysilane, the intermediate is a mixture of (acetoxyethylsilsesquioxane)-(acetoxyethyl-isobutyldimethoxysiloxy)siloxane copolymer, acetoxyethylsilsesquioxane, and isobutyltrimethoxysilane.

For the preferred solution coating method, the solution is generally formed by simply dissolving or suspending the silsesquioxane polymer in a solvent or mixture of solvents. The solvents which may be used in this method are preferably volatile, moderately polar solvents, which may include organic solvents selected from the group consisting of aromatic hydrocarbons and their epoxy-functional derivatives, glycol ethers, alkanes and their epoxy-functional derivatives, ketones, esters such as monomethylether acetate, orthoesters, chlorinated hydrocarbons, chlorofluorocarbons and alcohols. Exemplary organic solvents include diglyme (diethylene glycol dimethyl ether), dimethoxyethane, methoxyethylacetate, toluene, and alcohols such as ethanol, methoxypropanol, propoxypropanol and propylene glycol. Particularly preferred solvents include diglyme and methoxypropanol.

Halogen-gettering solvents are especially useful as coating solvents and these include orthoesters such as trimethylorthoformate and epoxy-functional solvents such as epoxybutane. These solvents are believed to be useful for their ability to react with byproduct hydrogen chloride or to react with intermediate Si—Cl-containing species and thus moderate the speed of reaction and eliminate corrosive byproducts.

The coating composition, a liquid containing the silsesquioxane base polymer with variable concentrations of alkoxysilanes or metal alkoxides which form reaction products of various composition, optionally in an organic solvent, is then applied to the substrate. Coating means such as spin, spray, dip or flow coating may be utilized. For application to circular substrates, the coating composition may be applied by the conventional spin-on glass (SOG) techniques, for example, so that a gradient is formed between the periphery and the center of the substrate.

Following application of the coating composition to the substrate, the coating solvent is allowed to evaporate by simple air drying, by exposure to an ambient environment, or by the application of a vacuum or mild heat.

Although the above-described methods primarily focus on using a solution approach, one skilled in the art would recognize in view of this disclosure that other equivalent means of coating (e.g., melt coating) would also function herein and are contemplated to be within the scope of this disclosure.

The formation of a SiO₂-rich structure, such as a film, is effected by processing the coated substrate, via treatment at moderately elevated temperatures or with UV irradiation, to convert the silsesquioxane deposition polymer composition into a SiO₂-rich ceramic thin film. This crosslinking conversion is carried out in a moisture-containing atmosphere containing at least about 0.5% relative humidity and preferably containing from about 15% relative humidity to about 100% relative humidity. The specified level of moisture may be present in the atmosphere during the entire processing procedure for forming the ceramic thin film or, alternatively, can be present during only a portion of the procedure. It should be noted that high levels of silanol groups (Si—OH) typically present in the silsesquioxane in either the base or deposition polymer also appear to facilitate the crosslinking reaction that occurs during the conversion procedure and may reduce the level of relative humidity required for efficient conversion of the silsesquioxane polymer into a SiO₂-rich ceramic thin film. One method for inducing silanol formation is to utilize silsesquioxane copolymers in which a hydrolyzable group is present, such as acetoxyethylsilsesquioxane-methoxypropoxysilsesquioxane copolymer, and expose them to a high humidity environment during deposition and before thermal or UV ceramification.

The other components in the moisture-containing atmosphere are not critical, and inert gases such as nitrogen, argon, helium or the like may be present or reactive gases such as air, oxygen, hydrogen chloride, ammonia and the like may be present.

In one embodiment of the present disclosure, the conversion of the silsesquioxane deposition polymer on the coated substrate is accomplished via thermal processing by heating the coated substrate. The temperature employed during the heating is moderate, preferably at least about 100° C., more preferably at least about 150° C. for choroethylsilsesqioxane or fluoride catalyzed, tetrabutylammonium fluoride, acetoxyethylsilsesquioxane resins. Extremely high temperatures, which are often deleterious to other materials present on the substrate, e.g., particularly metallized electronic substrates, are unnecessary. Heating temperatures in the range of about 150° C. to about 700° C. are preferable, with temperatures in the range of about 250° C. to about 500° C. for uncatalyzed silsesquioxane polymers being more preferred.

The exact temperature will depend on factors such as the particular β-substituted organosilsesquioxane base polymer utilized, the composition of the atmosphere (including relative humidity), heating time, coating thickness, and coating composition components, such as fluoride catalysts, all of which may affect conversion temperature. For example, the presence of fluoride has been found to dramatically reduce the resin conversion temperature and halide-substituted resins convert at lower temperatures than those containing acetoxy groups. In some cases, it may be desirable to remove any solvent present at temperatures below the ceramification to reduce stress-cracking. For example, evaporative removal of solvent by holding temperature between 50° and 120° C. prior to ceramification reduces the burst of outgassing that can occur if the dissolved deposition polymer is heated rapidly to ceramic conversion temperature which may negatively impact the ability to form films.

Heating is generally conducted for a time sufficient to form the desired SiO₂-rich ceramic thin film. The heating period typically is in the range of up to about 6 hours. Heating times of less than about 2 hours, e.g., about 0.1 to about 2 hours, are preferred.

The heating procedure is generally conducted at ambient pressure, i.e., atmospheric pressure, but subatmospheric pressure or a partial vacuum or superatmospheric pressures may also be employed. Any method of heating, such as the use of a convection oven, rapid thermal processing, hot plate, or radiant or microwave energy, is generally functional. The rate of heating, moreover, is also not critical, but it is most practical and preferred to heat as rapidly as possible.

In an alternative embodiment of the disclosure, the formation of a SiO₂-rich structure is accomplished by subjecting the coated substrate to ultraviolet (UV) irradiation. Exposure of the coated substrate to light at UV wavelengths has been found to effect the desired crosslinking conversion of the silsesquioxane polymer in the coated substrate. The UV irradiation treatment is ordinarily carried out without subjecting the coated substrate to the elevated temperatures used in the thermal processing, but combinations of the UV irradiation and thermal processing treatments could be employed, if desired.

The SiO₂-rich structure formed using UV light processing are generally characterized by having higher SiO₂ contents than typically result from thermal processing under otherwise identical coating conditions. An advantage of the use of UV processing is that patterned films may be generated on a substrate by the selective focusing of the UV irradiation.

The invention will now be described in connection with the following non-limiting examples.

### Example 1

Writing a gradient transparent glass-like ceramic structure was accomplished by utilizing three syringe pumps connected and feeding a mixing chamber adjacent to a dispensing orifice at the end of a tip. The mixture was dispensed onto a glass slide secured to a moving bed in order to provide a continuous film. The central larger syringe pump supplied a continuous flow of a freshly prepared 20% solution of 2-acetoxyethylsilsesquioxane base polymer as described in U.S. Pat. No. 6,770,726 in methoxypropanol. Two peripheral pumps contained (separately) isobutyltriethoxysilane and methoxy(polyethyleneoxy)propyltrimethoxysilane. The addition of silanes was independently varied between 5.5 v % and 0% of the silsesquioxane base polymer at the midpoint. That is, the concentration of the hydrophobic silane was decreased from 5.5 v % at the beginning of the deposition to 0 v % at the midpoint, and the concentration of the hydrophilic silane was increased from 0 v % at the midpoint to 5.5 v % at the end of the deposition. Thus, silsesquioxane deposition polymers of varying compositions were produced during the mixing. After solvent removal by heating at 110° C. for 4 hours in air, a clear film remained. Upon further heating to ˜250° C. with relative humidity (RH) ˜60%, the film turned translucent. The TGA weight loss in air of the solvent-free film was 47% at a temperature of 500° C. The control TGA of the base silsesquioxane was 44%. The comparative accorded well with the incorporation of the organofunctionality into the glass-like ceramic. One terminus was hydrophobic with a static water contact angle of 85° and the other terminus was relatively hydrophilic with a static water contact angle of 15°. When octadecyltrimethoxysilane was substituted for the isobutyltriethoxysilane under the same conditions, the static water contact angle was 100° at the hydrophobic terminus.

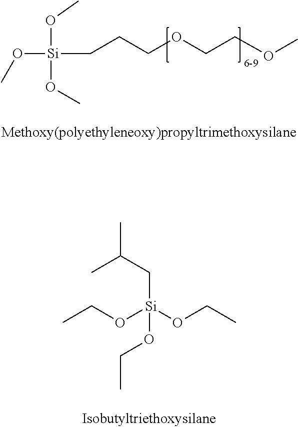

### Example 2 (Prophetic)

The base polymer of Example 1 is aged for approximately two weeks as a 20% solution in methoxypropanol. Acetoxy group migration from the 2-ethylsilicon to the silicon backbone followed by displacement by methoxypropanol to form the aetoxyethylsilsesquioxane-methoxypropoxysilsesquioxane copolymer is observed. The ratio of 2-ethylacetoxy groups to methoxypropyl groups is 6:1 and the resulting thin film ceramic material has a density of 1.55 g/mL. Gradient deposition is performed under the same conditions of Example 1.

### Example 3 (Prophetic)

The method described in Example 1 is repeated using germanium isopropoxide as a replacement for both silanes under the same conditions, increasing the refractive index.

### Example 4 (Prophetic)

The method described in Example 1 is repeated using dimethyldimethoxysilane as a replacement for one or both of the silanes under the same conditions, decreasing the modulus of the coating.

It will be appreciated by those skilled in the art that changes could be made to the embodiment described above without departing from the broad inventive concepts thereof. Also, based on this disclosure, a person of ordinary skill in the art would further recognize that the relative proportions of the components illustrated above could be varied without departing from the spirit and scope of the invention. It is understood, therefore, that this invention is not limited to that particular embodiment disclosed, but it is intended to cover modifications within the spirit and scope of the present invention as defined by the appended claims.

We claim:

1. A SiO₂-rich structure having gradient properties, wherein the structure is formed from a silsesquioxane having an electronegative β substituent and at least one organofunctional silane.

2. The SiO₂-rich structure according to claim 1, wherein the structure has gradient hydrophobicity/hydrophilicity properties.

3. The SiO₂-rich structure according to claim 1, wherein the silsesquioxane has a halogen, ether, or carboxylate functional group in the β position.

4. The SiO₂-rich structure according to claim 3, wherein the silsesquioxane is 2-acetoxyethylsilsesquioxane.

5. The SiO₂-rich structure according to claim 1, wherein the at least one organofunctional silane is a dialkyldialkoxysilane or an alkyltrialkoxysilane.

6. The SiO₂-rich structure according to claim 5, wherein the at least one organofunctional silane is a dialkyldimethoxysilane or a dialkyldiethoxysilane.

7. The SiO₂-rich structure according to claim 5, wherein the at least one organofunctional silane is an alkyltrimethoxysilane or an alkyltriethoxysilane.

8. The SiO₂-rich structure according to claim 5, wherein the at least one organofunctional silane is methoxy(polyethyleneoxy)propyltrimethoxysilane or isobutyltriethoxysilane.

9. The SiO₂-rich structure according to claim 1, wherein the structure is formed from 2-acetoxyethylsilsesquioxane, methoxy(polyethyleneoxy)propyltrimethoxysilane, and isobutyltriethoxysilane.

10. A SiO₂-rich structure having a gradient concentration of at least one metal oxide selected from the group consisting of oxides of germanium, tantalum, titanium, zirconium and hafnium, wherein the structure is formed from a metal alkoxide having the same metal as the at least one metal oxide and a silsesquioxane having an electronegative β substituent, wherein a plurality of silicon atoms are each bonded to four oxygen atoms and no more than about 50% of the silicon atoms are bonded to carbon atoms.

11. The SiO₂-rich structure according to claim 10, wherein the SiO₂-rich structure has a gradient refractive index.

12. The SiO₂-rich structure according to claim 1, wherein a plurality of silicon atoms are each bonded to four oxygen atoms and no more than about 50% of the silicon atoms are bonded to carbon atoms.

13. The SiO₂-rich structure according to claim 1, wherein the structure is a ceramic film.

14. The SiO₂-rich structure according to claim 13, wherein the ceramic film has a thickness of about 15 to about 500 nm.

15. A method for forming a SiO₂-rich structure having a gradient property, the method comprising preparing a coating composition comprising a silsesquioxane having an electronegative β substituent, at least one organofunctional silane, and optionally a solvent, coating the mixture onto a substrate, and heating and/or UV irradiating the coated substrate.

16. The method according to claim 15, wherein the coating composition comprises a volatile polar solvent.

17. The method according to claim 15, wherein the coating comprises spin-on deposition, 3-D printing, microcontact printing, or direct writing.

18. The method according to claim 15, wherein the heating and/or UV irradiating is performed in an atmosphere containing at least about 0.5% relative humidity.

19. The method according to claim 15, wherein the heating is performed at about 150° C. to about 700° C.

20. The method according to claim 15, wherein the coating step comprises adjusting relative flow rates of the at least one organofunctional silane.

21. The method according to claim 15, wherein the coating composition comprises varying amounts of the at least one organofunctional silane.

22. A method for forming a SiO₂-rich structure having a gradient property, the method comprising preparing a coating composition comprising a silsesquioxane having an electronegative β substituent, at least one metal alkoxide, and optionally a solvent, coating the mixture onto a substrate, and heating and/or UV irradiating the coated substrate.

23. The method according to claim 22, wherein the metal alkoxide is selected from the group consisting of germanium isopropoxide, tantalum ethoxide, titanium n-butoxide, zirconium n-propoxide, and hafnium n-butoxide.

24. The method according to claim 22, wherein the SiO₂-rich structure has a gradient refractive index.

25. The method according to claim 22, wherein the SiO₂-rich structure has a gradient metal oxide concentration.

26. The method according to claim 22, wherein the coating step comprises adjusting relative flow rates of the at least one metal alkoxide.

27. The method according to claim 22, wherein the coating composition comprises varying amounts of the at least one metal alkoxide.
